(19) United States
(12) Patent Application Publication
(10) Pub. No.: US 2010/0067646 A1
(43) Pub. Date: Mar. 18, 2010

(54) SHIFT REGISTER WITH EMBEDDED BIDIRECTIONAL SCANNING FUNCTION

(75) Inventors: Kuang-Hsiang LIU, Hsinchu (TW); Chen-Ming CHEN, Hsinchu (TW); Sheng-Chao LIU, Hsinchu (TW); Ming-Tien LIN, Hsinchu (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: AU OPTRONICS CORPORATION, Hsinchu (TW)

(21) Appl. No.: 12/212,143

(22) Filed: Sep. 17, 2008

(51) Int. Cl. G11C 19/00

(52) U.S. Cl. 377/69; 377/79

(57) ABSTRACT

A shift register comprises a plurality of stages, {Sⱼ}, j=1, 2, . . . , N, N being a positive integer. Each stage Sⱼ includes a first input, IN1, a second input, IN2, a third input, IN3, a fourth input, IN4, a fifth input, IN5 and a sixth input, IN6; an output, OUT; a first transistor M1 having a gate electrically coupled to the third input IN3, a drain electrically coupled to the first input IN1, and a source electrically coupled to a node N1, respectively; a second transistor M2 having a gate electrically coupled to the fourth input IN4, a drain electrically coupled to the node N1, and a source electrically coupled to the second input IN2, respectively; a third transistor M3 having a gate electrically coupled to a node N2 that is electrically coupled to the node N1, a drain electrically coupled to the fifth input IN5, and a source electrically coupled to the output OUT, respectively; and a fourth transistor M4 having a gate electrically coupled to a node N3, a drain electrically coupled to the output OUT, and a source electrically coupled to the sixth input IN6, respectively.

### FIELD OF THE INVENTION

The present invention relates generally to a shift register, and in particular to a shift register with an embedded bidirectional scanning function.

### BACKGROUND OF THE INVENTION

A liquid crystal display (LCD) includes an LCD panel formed with liquid crystal cells and pixel elements with each associating with a corresponding liquid crystal cell. These pixel elements are substantially arranged in the form of a matrix having gate lines in rows and data lines in columns. The LCD panel is driven by a driving circuit including a gate driver and a data driver. The gate driver generates a plurality of gate signals (scanning signals) sequentially applied to the gate lines for sequentially turning on the pixel elements row-by-row. The data driver generates a plurality of source signals (data signals), i.e., sequentially sampling image signals, simultaneously applied to the data lines in conjunction with the gate signals applied to the gate lines for aligning states of the liquid crystal cells on the LCD panel to control light transmittance therethrough, thereby displaying an image on the LCD.

In such a driving circuit, a bi-directional shift register is usually utilized in the gate driver to generate the plurality of gate signals for sequentially driving the gate lines, so as to allow a positive or a reverse display image. Typically, a plurality of 2-to-2 bi-directional control circuits is employed in the bi-directional shift register to control the scanning direction, forward or backward, of the plurality of gate signals.

FIG. 6 illustrates a conventional bi-directional shift register 600, where three shift register stages 610, 620 and 630 serially connected through three 2-to2 bi-directional control circuits 615, 625 and 635, respectively, are shown. Each register stage includes at least two input terminals K1 and K2 and an output terminal O. The 2-to-2 bi-directional control circuit shown in FIG. 7 has two input terminals P and N, and two output terminals D1 and D2, and are operably controlled by two control signals Bi and XBi. The control signals Bi and XBi are two DC signals set to have opposite polarities, such as a high level voltage and a low level voltage, and used to set the 2-to 2 bi-directional control circuits 615, 625, and 635 in a manner to direct input signals in the shift register 600 to be shifted in a forward or backward direction.

In the shift register 600, the input terminals K1 and K2 of each register stage are electrically coupled to the output terminals DI and D2 of a corresponding 2-to2 bi-directional control circuit, respectively, while the output terminal O of each register stage is electrically coupled to the terminal N of the immediately prior 2-to2 bi-directional control circuit and the terminal P of the immediately next 2-to2 bi-directional control circuit. Thus, the output terminal O of the register stage 620 provides an input to the 2-to2 bi-directional control circuits 615 and 635. For such a shift register 600, when Bi is the high level voltage and XBi is the low level voltage, an input pulse will be shifted from the stage 610 to the stage 630 in the forward direction, while the input pulse will be shifted from the stage 630 to the stage 610 in the backward direction when Bi is the low level voltage and XBi is the high level voltage.

However, the use of the 2-to 2 bi-directional control circuit in each stage of the shift register may cause voltage drops in input signals of the stage, and increase power consumption and manufacture costs.

Therefore, a heretofore unaddressed need exists in the art to address the aforementioned deficiencies and inadequacies.

### SUMMARY OF THE INVENTION

The present invention, in one aspect, relates to a shift register. In one embodiment, the shift register includes a first control line for providing a first bi-directional control signal, Bi, a second control line for providing a second bi-directional control signal, XBi, a first clock signal line for providing a first clock signal, Ck, a second clock signal line for providing a second clock signal, XCk, and a reference line for providing a supply voltage, Vss.

In one embodiment, each of the first bi-directional control signal Bi and the second bi-directional control signal XBi comprises an AC signal characterized with a frequency and a phase, where the frequency of the first bi-directional control signal and the frequency of the second bi-directional control signal are substantially identical and the phase of the first bi-directional control signal and the phase of the second bi-directional control signal are substantially reversed.

In another embodiment, each of the first bi-directional control signal Bi and the second bi-directional control signal XBi comprises a DC signal characterized with a constant voltage, where when the first bi-directional control signal Bi has a high voltage, the second bi-directional control signal XBi has a low voltage, and vice versa.

In yet another embodiment, one of the first bi-directional control signal Bi and the second bi-directional control signal XBi comprises an AC signal, and the other of the first bi-directional control signal Bi and the second bi-directional control signal XBi comprises a DC signal.

In one embodiment, each of the first clock signal Ck and the second clock signal XCk is characterized with a frequency and a phase, where the frequency of the first clock signal Ck and the frequency of the second clock signal XCk is substantially identical and the phase of the first clock signal Ck and the phase of the second clock signal XCk is substantially reversed.

Furthermore, the shift register includes a plurality of stages, {Sⱼ}, j=1, 2, . . . , N, N being a positive integer. Each stage Sⱼ comprises a first input, IN1, a second input, IN2, a third input, IN3, a fourth input, IN4, a fifth input, IN5, electrically coupled to one of the first clock signal line and the second clock signal line when j is an odd number, or the other of the first clock signal line and the second clock signal line when j is an even number, a sixth input, IN6, electrically coupled to the reference line, and an output, OUT, for outputting an output signal, Sout(j), a first transistor M1 having a gate electrically coupled to the third input IN3, a drain electrically coupled to the first input IN1, and a source electrically coupled to a node N1, respectively, a second transistor M2 having a gate electrically coupled to the fourth input IN4, a drain electrically coupled to the node N1, and a source electrically coupled to the second input IN2, respectively, a third transistor M3 having a gate electrically coupled to a node N2 that is electrically coupled to the node N1, a drain electrically coupled to the fifth input IN5, and a source electrically coupled to the output OUT, respectively, and a fourth transistor M4 having a gate electrically coupled to a node N3, a drain electrically coupled to the output OUT, and a source electrically coupled to the sixth input IN6, respectively.

In one embodiment, if both the first bi-directional control signal Bi and the second bi-directional control signal XBi are DC signals, the first input IN1 and the second input IN2 of the stage Sⱼ are electrically coupled to the first control line and the second control line, respectively. In an embodiment, if both the first bi-directional control signal Bi and the second bi-directional control signal XBi are AC signals, the first input IN1 and the second input IN2 of the stage Sⱼ are electrically coupled to the first control line and the second control line, respectively, when j is an odd number, and the first input IN1 and the second input IN2 of the stage Sⱼ are electrically coupled to the second control line and the first control line, respectively, when j is an even number.

Each stage Sⱼ further comprises a disable circuit adapted for operably disabling an output of the stage Sⱼ.

The plurality of stages {Sⱼ} is electrically coupled in serial such that the third input IN3 of the i-th stage Sᵢ, i=2, 3, 4, . . . N, is electrically coupled to the output OUT of the (i−1)-th stage Sᵢ₋₁, for receiving a corresponding output signal Sout(i−1) therefrom, and the fourth input IN4 of the k-th stage Sₖ, k=1, 2, 3, . . . (N−1), is electrically coupled to the output OUT of the (k+1)-th stage Sₖ₊₁, for receiving a corresponding output signal Sout(k+1) therefrom.

Additionally, the shift register also includes a first start pulse input line 119a electrically coupled to the third input IN3 of the first stage S₁ for providing a first start pulse, Sp1, thereto, and a second start pulse input line electrically coupled to the third input IN4 of the last stage S_{N} for providing a second start pulse, Sp2, thereto.

In another aspect, the present invention relates to a shift register. In one embodiment, the shift register includes a plurality of stages, {Sⱼ}, j=1, 2, . . . , N, N being a positive integer. Each stage Sⱼ comprises a first input, IN1, a second input, IN2, a third input, IN3, a fourth input, IN4, a fifth input, IN5 and a sixth input, IN6, an output, OUT, a first transistor M1 having a gate electrically coupled to the third input IN3, a drain electrically coupled to the first input IN1, and a source electrically coupled to a node N1, respectively, a second transistor M2 having a gate electrically coupled to the fourth input IN4, a drain electrically coupled to the node N1, and a source electrically coupled to the second input IN2, respectively, a third transistor M3 having a gate electrically coupled to a node N2 that is electrically coupled to the node N1, a drain electrically coupled to the fifth input IN5, and a source electrically coupled to the output OUT, respectively, and a fourth transistor M4 having a gate electrically coupled to a node N3, a drain electrically coupled to the output OUT, and a source electrically coupled to the sixth input IN6, respectively. In one embodiment, each of the first transistor M1, the second transistor M2, the third transistor M3, and the fourth transistor M4 comprises a field-effect thin film transistor.

In one embodiment, each stage Sⱼ further comprises a disable circuit adapted for operably disabling an output of the stage Sⱼ.

The plurality of stages {Sⱼ} is electrically coupled in serial such that the third input IN3 of the i-th stage Sᵢ, i=2, 3, 4, . . . N, is electrically coupled to the output OUT of the (i−1)-th stage Sᵢ₋₁, for receiving a corresponding output signal Sout(i−1) therefrom, and the fourth input IN4 of the k-th stage Sₖ, k=1, 2, 3, . . . (N−1), is electrically coupled to the output OUT of the (k+1)-th stage Sₖ₊₁, for receiving a corresponding output signal Sout(k+1) therefrom.

Furthermore, the shift register includes a first start pulse input line 119a electrically coupled to the third input IN3 of the first stage S₁ for providing a first start pulse, Sp1, thereto, and a second start pulse input line electrically coupled to the third input IN4 of the last stage S_{N} for providing a second start pulse, Sp2, thereto.

Moreover, the shift register includes a first control line for providing a first bi-directional control signal Bi, and a second control line for providing a second bi-directional control signal XBi. In one embodiment, each of the first bi-directional control signal Bi and the second bi-directional control signal XBi comprises an AC signal characterized with a frequency and a phase, where the frequency of the first bi-directional control signal and the frequency of the second bi-directional control signal are substantially identical and the phase of the first bi-directional control signal and the phase of the second bi-directional control signal are substantially reversed. In another embodiment, each of the first bi-directional control signal Bi and the second bi-directional control signal XBi comprises a DC signal characterized with a constant voltage, where when the first bi-directional control signal Bi has a high voltage, the second bi-directional control signal XBi has a low voltage, and vice versa. In yet another embodiment, one of the first bi-directional control signal Bi and the second bi-directional control signal XBi comprises an AC signal, and the other of the first bi-directional control signal Bi and the second bi-directional control signal XBi comprises a DC signal.

In one embodiment, if both the first bi-directional control signal Bi and the second bi-directional control signal XBi are DC signals, the first input IN1 and the second input IN2 of the stage Sⱼ are electrically coupled to the first control line and the second control line, respectively. In an embodiment, if both the first bi-directional control signal Bi and the second bi-directional control signal XBi are AC signals, the first input IN1 and the second input IN2 of the stage Sⱼ are electrically coupled to the first control line and the second control line, respectively, when j is an odd number, and the first input IN1 and the second input IN2 of the stage Sⱼ are electrically coupled to the second control line and the first control line, respectively, when j is an even number.

Additionally, the shift register includes a first clock signal line for providing a first clock signal, Ck, and a second clock signal line for providing a second clock signal, XCk, and where the fifth input IN5 of the stage Sⱼ is electrically coupled to the first clock signal line when j is an odd number, or the second clock signal line when j is an even number. In one embodiment, each of the first clock signal Ck and the second clock signal XCk is characterized with a frequency and a phase, where the frequency of the first clock signal Ck and the frequency of the second clock signal XCk is substantially identical and the phase of the first clock signal Ck and the phase of the second clock signal XCk is substantially reversed.

The shift register also includes a reference line electrically coupled to the sixth input IN6 of each stage Sⱼ for providing the supply voltage Vss thereto.

In yet another aspect, the present invention relates to a shift register. In one embodiment, the shift register includes a plurality of stages, {Sⱼ}, j=1, 2, . . . , N, N being a positive integer. Each stage Sⱼ comprises a first input, IN1, for receiving one of a first bi-directional control signal, Bi, and a second bi-directional control signal, XBi, a second input, IN2, for receiving the other of the first bi-directional control signal Bi and the second bi-directional control signal XBi, a third input, IN3, a fourth input, IN4, a fifth input, IN5, for receiving a clock signal, a sixth input, IN6, for receiving a supply voltage, Vss, and an output, OUT, for outputting an output signal, Sout(j), where the plurality of stages {Sⱼ} is electrically coupled in serial such that the third input IN3 of the i-th stage Sᵢ, i=2, 3, 4, . . . N, is electrically coupled to the output OUT of the (i−1)-th stage Sᵢ₋₁, for receiving a corresponding output signal Sout(i−1) therefrom, and the fourth input IN4 of the k-th stage Sₖ, k=1, 2, 3, . . . (N−1), is electrically coupled to the output OUT of the (k+1)-th stage Sₖ₊₁, for receiving a corresponding output signal Sout(k+1) therefrom

The shift register further includes a start pulse input line electrically coupled to the third input IN3 of the first stage S₁ for providing a start pulse, Sp, thereto.

Additionally, the shift register also includes a first control line for providing the first bi-directional control signal Bi, and a second control line for providing the second bi-directional control signal XBi, where the first bi-directional control signal Bi and the second bi-directional control signal XBi are configured such that when the first bi-directional control signal Bi has a high voltage, the second bi-directional control signal XBi has a low voltage, and vice versa.

Furthermore, the shift register includes a first clock signal line for providing a first clock signal, Ck, and a second clock signal line for providing a second clock signal, XCk, and where the fifth input IN5 of the stage Sⱼ is electrically coupled to one of the first clock signal line and the second clock signal line when j is an odd number, or the other of the first clock signal line and the second clock signal line when j is an even number. The shift register also includes a reference line electrically coupled to the sixth input IN6 of each stage Sⱼ for providing the supply voltage Vss.

In one embodiment, each stage Sⱼ further has a first transistor M1 having a gate electrically coupled to the third input IN3, a drain electrically coupled to the first input IN1, and a source electrically coupled to a node N1, respectively, a second transistor M2 having a gate electrically coupled to the fourth input IN4, a drain electrically coupled to the node N1, and a source electrically coupled to the second input IN2, respectively, a third transistor M3 having a gate electrically coupled to a node N2 that is electrically coupled to the node N 1, a drain electrically coupled to the fifth input IN5, and a source electrically coupled to the output OUT, respectively, and a fourth transistor M4 having a gate electrically coupled to a node N3, a drain electrically coupled to the output OUT, and a source electrically coupled to the sixth input IN6, respectively, where each of the first transistor M1, the second transistor M2, the third transistor M3, and the fourth transistor M4 comprises a field-effect thin film transistor.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and, together with the written description, serve to explain the principles of the invention. Wherever possible, the same reference numbers are used throughout the drawings to refer to the same or like elements of an embodiment, and wherein:

FIG. 1A shows a block diagram of a shift register having an odd number of stages according to one embodiments of the present invention;

FIG. 1B shows a block diagram of a shift register having an even number of stages according to one embodiments of the present invention;

FIG. 1C shows a block diagram of a shift register having an odd number of stages according to one embodiments of the present invention;

FIG. 1D shows a block diagram of a shift register having an even number of stages according to one embodiments of the present invention;

FIG. 2 shows a circuit diagram of a stage of a shift register according to one embodiment of the present invention;

FIG. 3 shows a timing chart of input and output signals of a shift register according to one embodiment of the present invention;

FIG. 4 shows a timing chart of input and output signals of a shift register according to another embodiment of the present invention;

FIG. 5 shows a timing chart of input and output signals of a shift register according to yet another embodiment of the present invention;

FIG. 6 shows a block diagram of a conventional shift register; and

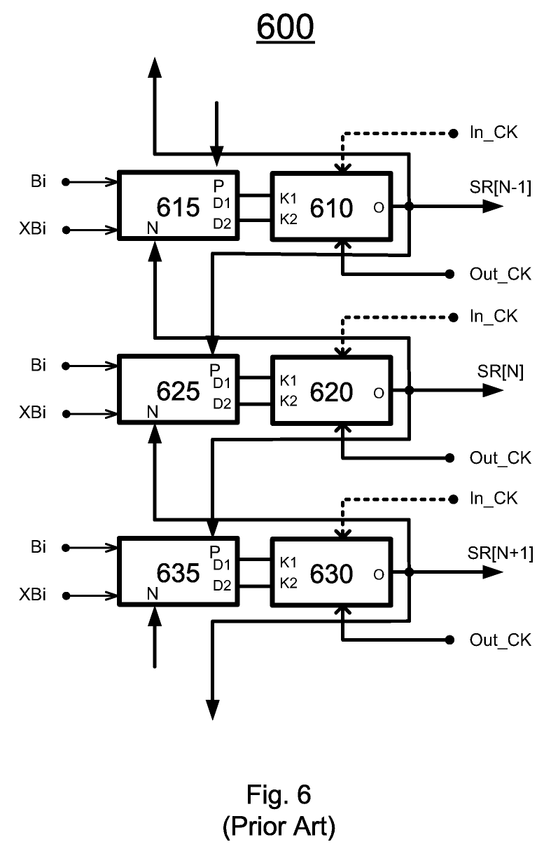

FIG. 7 shows a conventional 2-to-2 bi-directional control circuit.

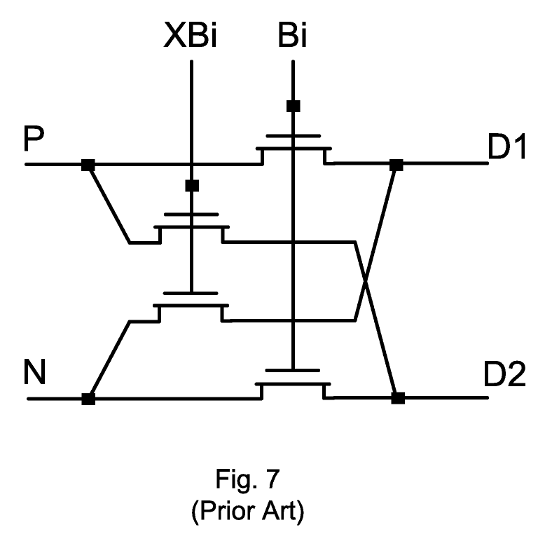

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise.

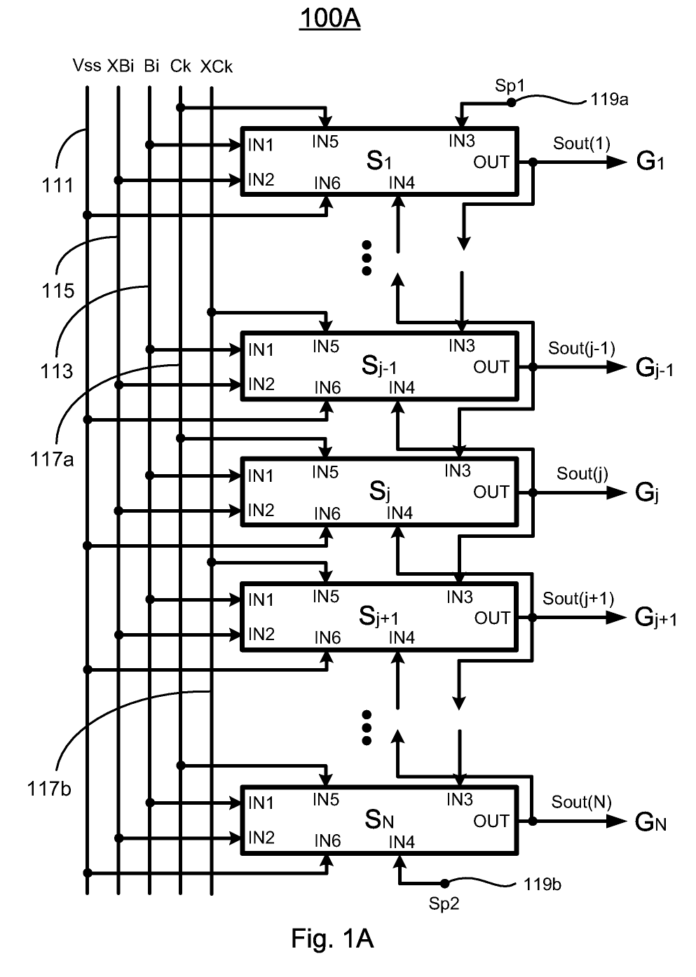

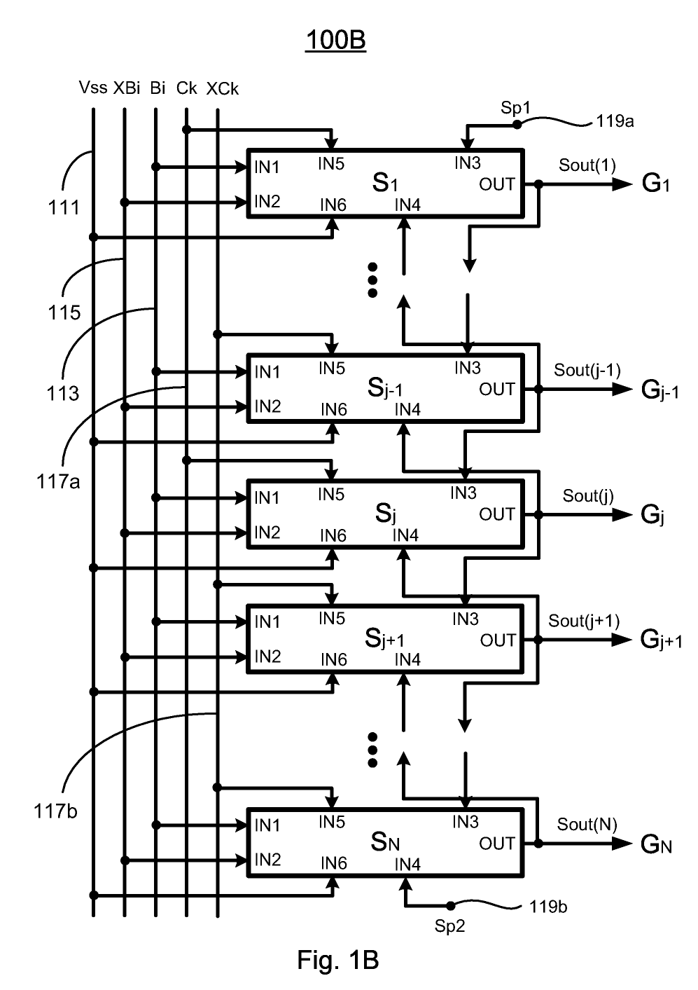

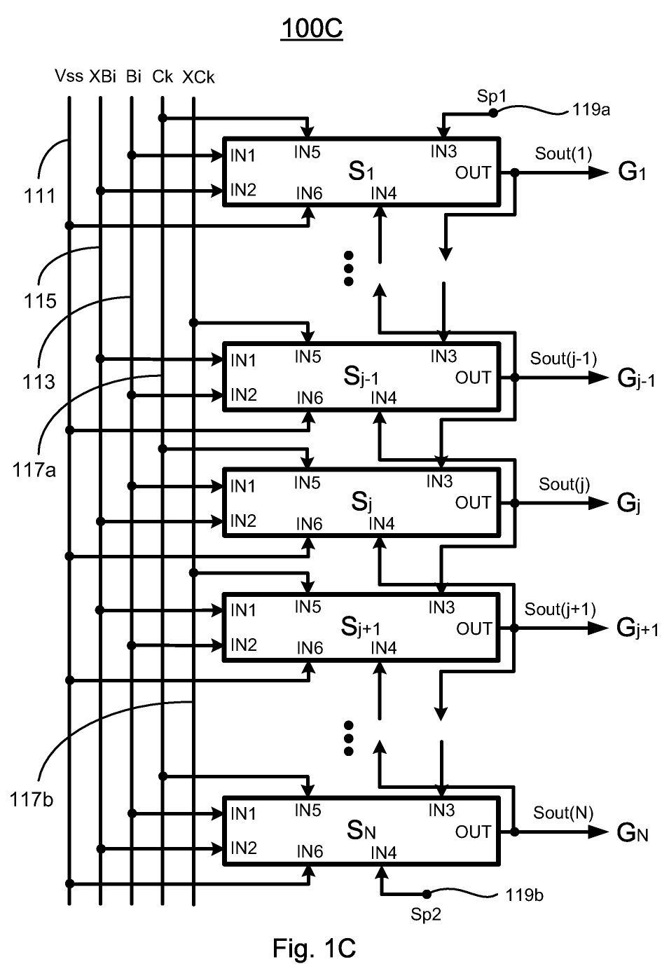

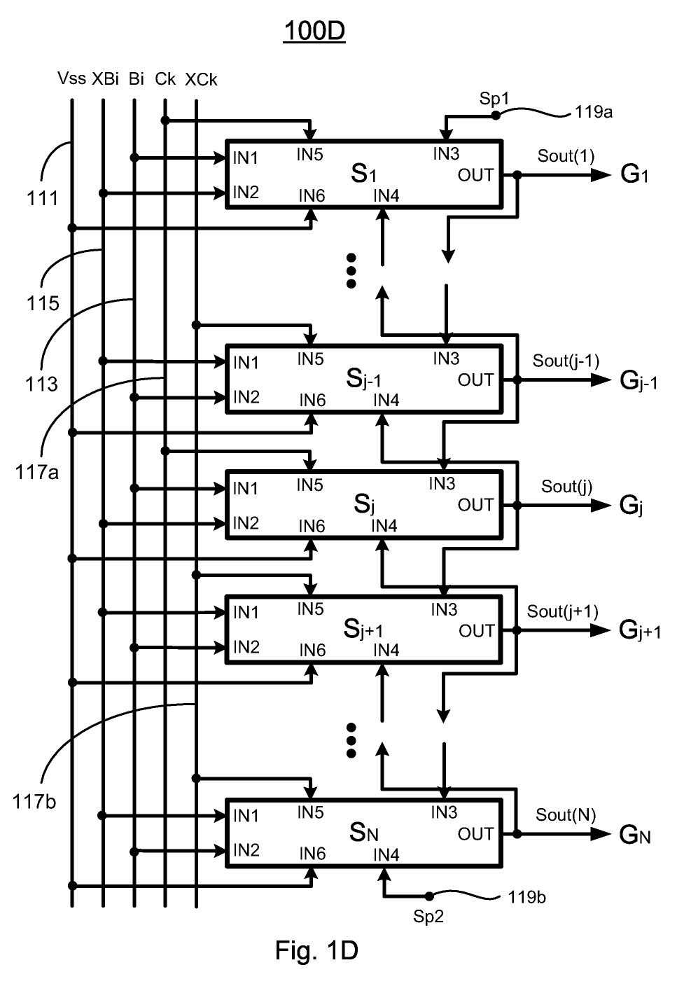

The description will be made as to the embodiments of the present invention in conjunction with the accompanying drawings in FIGS. 1A-1D and 2-5. In accordance with the purposes of this invention, as embodied and broadly described herein, this invention, in one aspect, relates to a shift register with embedded bidirectional scanning function.

Referring in general to FIGS. 1A-1D and 2-5, and in particular to FIGS. 1A-1D first, each of FIGS. 1A-1D shows a shift register 100A, 100B, 100C or 100D, respectively, according to one embodiment of the present invention. The shift register 100A, 100B, 100C or 100D includes a reference line 111 for providing a supply voltage, Vss, a first control line 113 for providing a first bi-directional control signal, Bi, and a second control line 115 for providing a second bi-directional control signal, XBi.

In one embodiment, each of the first bi-directional control signal Bi and the second bi-directional control signal XBi comprises an AC signal characterized with a frequency and a phase, where the frequency of the first bi-directional control signal and the frequency of the second bi-directional control signal are substantially identical and the phase of the first bi-directional control signal and the phase of the second bi-directional control signal are substantially reversed.

In another embodiment, each of the first bi-directional control signal Bi and the second bi-directional control signal XBi comprises a DC signal characterized with a constant voltage, where when the first bi-directional control signal Bi has a high voltage, the second bi-directional control signal XBi has a low voltage, and vice versa. In one embodiment, one of the first bi-directional control signal Bi and the second bi-directional control signal XBi is a high voltage Vdd, while the other of the first bi-directional control signal Bi and the second bi-directional control signal XBi is a low voltage Vss. The low voltage Vss is supplied to the ground, and thus can be a ground voltage or a negative voltage.

In yet another embodiment, one of the first bi-directional control signal Bi and the second bi-directional control signal XBi comprises an AC signal, and the other of the first bi-directional control signal Bi and the second bi-directional control signal XBi comprises a DC signal.

Furthermore, the shift register 100A, 100B, 100C or 100D includes a first clock signal line 117a for providing a first clock signal, Ck, and a second clock signal line 117b for providing a second clock signal, XCk. Each of the first clock signal Ck and the second clock signal XCk is characterized with a frequency and a phase. In one embodiment, the frequency of the first clock signal Ck and the frequency of the second clock signal XCk is substantially identical and the phase of the first clock signal Ck and the phase of the second clock signal XCk is substantially reversed.

Moreover, the shift register 100A, 100B, 100C or 100D includes a first start pulse input line 119a for providing a first start pulse, Sp1, and a second start pulse input line 119b for providing a second start pulse, Sp2. As shown below, the first start pulse Sp1 servers as a start pulse signal in a forward function operation of the shift register, and the second start pulse Sp2 servers as a start pulse signal in a backward function operation of the shift register.

As shown in FIGS. 1A-1D, the shift register 100A, 100B, 100C or 100D further includes a plurality of stages, {Sⱼ}, j=1, 2, . . . , N, N being a positive integer. Each stage Sⱼ has a first input, IN1, a second input, IN2, a third input, IN3, a fourth input, IN4, a fifth input, IN5, a sixth input, IN6, and an output, OUT. In general, the sixth input IN6 is electrically coupled to the reference line 111 for receiving supply voltage Vss therefrom, and the output OUT is adapted for outputting an output signal, Sout(j).

The fifth input IN5 can be electrically coupled to the first clock signal line 117a or the second clock signal line 117b, depending on whether j is an odd number or an even number. In one embodiment, when j is an odd number, the fifth input IN5 is electrically coupled to the first clock signal line 117a, and when j is an even number, the fifth input IN5 is electrically coupled to the second clock signal line 117b. For example, in the exemplary embodiment shown in FIG. 1A, the fifth input IN5 of the first stage S₁ is electrically coupled to the first clock signal line 117a for receiving the first clock signal Ck therefrom, . . . the fifth input IN5 of the (j−1)-th stage Sⱼ₋₁ is electrically coupled to the second clock signal line 117b for receiving the second clock signal XCk therefrom, the fifth input IN5 of the j-th stage Sⱼ is electrically coupled to the first clock signal line 117a for receiving the first clock signal Ck therefrom, and the fifth input IN5 of the (j+1)-th stage Sⱼ₊₁ is electrically coupled to the second clock signal line 117b for receiving the second clock signal XCk therefrom, . . . and the fifth input IN5 of the N-th stage S_{N} is electrically coupled to the first clock signal line 117a for receiving the first clock signal Ck therefrom. In another embodiment, when j is an odd number, the fifth input IN5 is electrically coupled to the second clock signal line 117b, and when j is an even number, the fifth input IN5 is electrically coupled to the first clock signal line 117a.

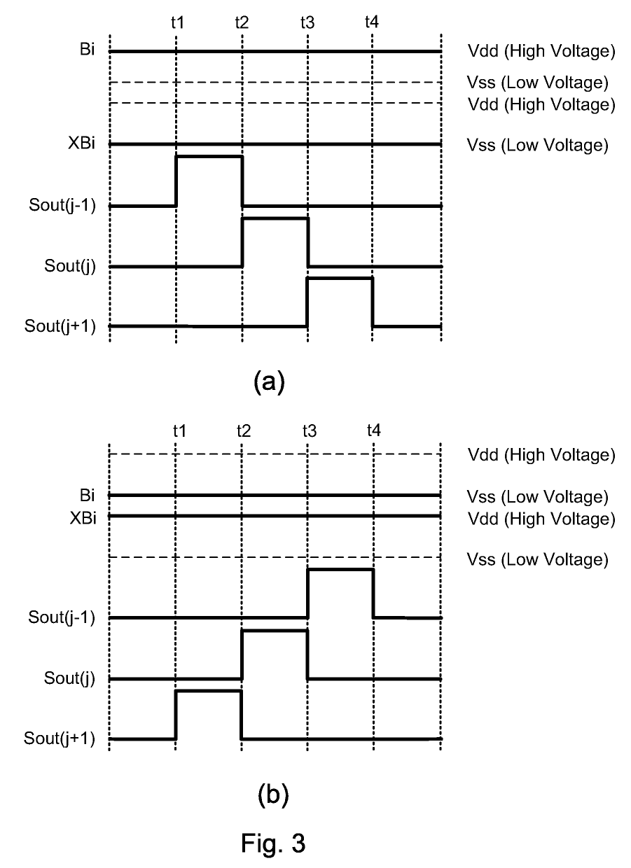

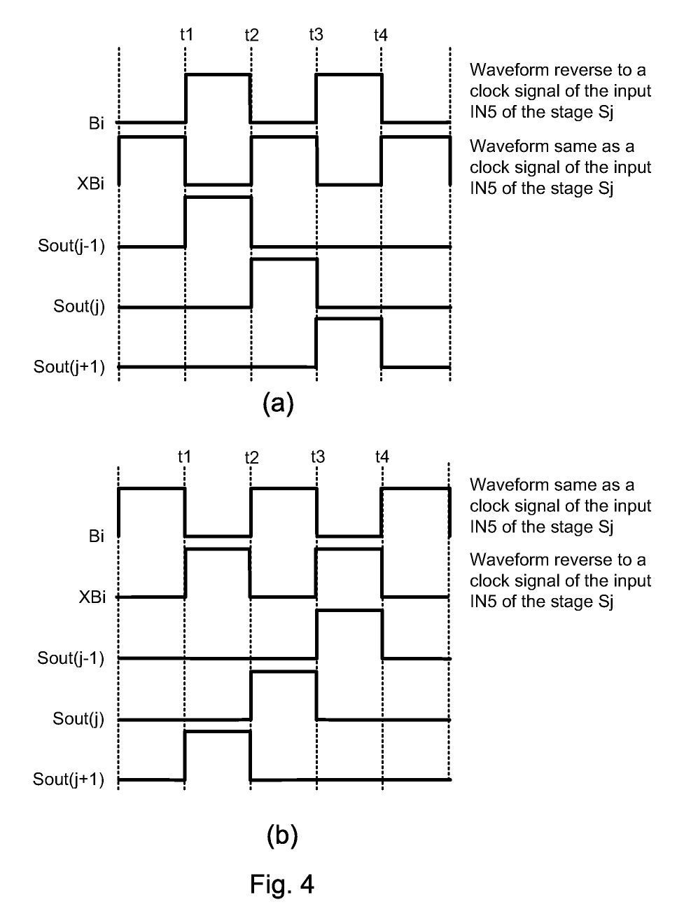

Each of the first input IN1 and the second input IN2 can be electrically coupled to the first control line 113 for receiving the first bi-directional control signal Bi therefrom, or the second control line 115 for receiving the second bi-directional control signal XBi therefrom, depending on whether the first bi-directional control signal Bi and the second bi-directional control signal XBi are DC signals or AC signals and whether j is an odd number or an even number. If both the first bi-directional control signal Bi and the second bi-directional control signal XBi are DC signals, the first input IN1 and the second input IN2 are electrically coupled to the first control line 113 and the second control line 115, respectively, no matter whether j is an odd number or an even number, as shown in FIGS. 3, 1A and 1B. However, if both the first bi-directional control signal Bi and the second bi-directional control signal XBi are AC signals, the first input IN1 and the second input IN2 are electrically coupled to the first control line 113 and the second control line 115, respectively, when j is an odd number, and the first input IN1 and the second input IN2 are electrically coupled to the second control line 115 and the first control line 113, respectively, when j is an even number, as shown in FIGS. 4, 1C and 1D.

The plurality of stages {Sⱼ} are electrically coupled to each other in serial. Specifically, for the first stage S₁, the third input IN3 of the first stage S₁ is electrically coupled to the first start pulse input line 119a for receiving the first start pulse Sp1 therefrom, and the fourth input IN4 of the first stage S₁ is electrically coupled to the output OUT of the second stage S₂. For the second and other stage Sᵢ, i=2, 3, 4, . . . N, the third input IN3 of the i-th stage Sᵢ is electrically coupled to the output OUT of the (i−1)-th stage Sᵢ₋₁, for receiving a corresponding output signal Sout(i−1) from the (i−1)-th stage Sᵢ₋₁. Furthermore, the fourth input IN4 of the k-th stage Sₖ, k=1, 2, 3, . . . (N−1), is electrically coupled to the output OUT of the (k+1)-th stage Sₖ₋₁, for receiving a corresponding output signal Sout(k+1) from the (k+1)-th stage Sₖ₊₁. For the N-th stage S_{N}, the fourth input IN4 of the stage S_{N} is electrically coupled to the second start pulse input line 119b for receiving the second start pulse Sp2 therefrom.

Additionally, the output OUT of each stage Sⱼ is also electrically coupled to a corresponding gate line, Gⱼ, of an LCD panel for providing the output signal Sout(j) to drive the corresponding gate line Gⱼ accordingly.

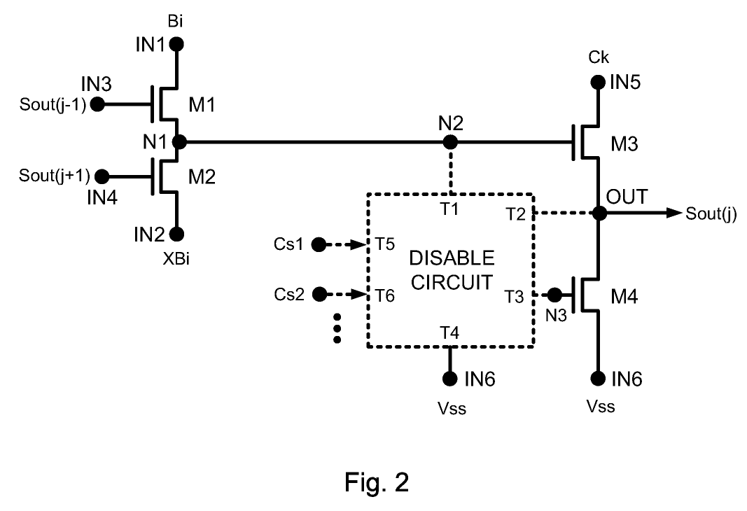

Referring now to FIG. 2, each stage Sⱼ further has a first transistor M1 having a gate electrically coupled to the third input IN3, a drain electrically coupled to the first input IN1, and a source electrically coupled to a node N1, respectively, and a second transistor M2 having a gate electrically coupled to the fourth input IN4, a drain electrically coupled to the node N1, and a source electrically coupled to the second input IN2, respectively. Each stage Sⱼ also has a third transistor M3 having a gate electrically coupled to a node N2 that is electrically coupled to the node N1, a drain electrically coupled to the fifth input IN5, and a source electrically coupled to the output OUT, respectively, and a fourth transistor M4 having a gate electrically coupled to a node N3, a drain electrically coupled to the output OUT, and a source electrically coupled to the sixth input IN6, respectively. The first and second transistors M1 and M2 are input transistors, and adapted for providing a bi-directional shift function, i.e., the forward shift function or the backward shift function. The third transistor M3 is an output transistor, while the fourth transistor M4 is a pull-down transistor. Preferably, at least one of the first transistor M1, the second transistor M2, the third transistor M3, and the fourth transistor M4 is a field-effect thin film transistor (TFT). Other types of TFTs can also be used to practice the current invention.

Additionally, each stage Sⱼ further has a disable circuit. In this exemplary embodiment, the disable circuit has a first terminal T1 electrically coupled to the node N2, a second terminal T2 electrically coupled to the output OUT, a third terminal T3 electrically coupled to the node N3, a fourth terminal T4 electrically coupled to the sixth input IN6, a fifth terminal T5 for receiving a first disable circuit control signal, Cs1, and a sixth terminal T6 for receiving a second disable circuit control signal, Cs2. Other numbers of terminals can also be used to practice the present invention. The terminals T1-T6 of the disable circuit are adapted for receiving input signals and/or for outputting output signals, which can be a boost signal, clock signals, power signals, output signals Sout(m) of other stages Sm (m≠j) of the shift register 100, and/or the output signal Sout(j) of its stage Sⱼ of the shift register 100. The node N2 corresponds to a boost point in this embodiment as shown in FIG. 2. The disable circuit is configured to generate one or more signals responsive to the input pulses so as to disable the shifter register when an abnormal state occurs.

An operation procedure of the shift register will be described with reference to driving waveforms illustrated in FIG. 3 and the stage circuit shown in FIG. 2.

Referring now to FIG. 3, timing charts (waveforms) of input and output signals of the shift register at the (j−1)-th, j-th and (j+1)-th stages Sⱼ₋₁, Sⱼ and Sⱼ₊₁ are shown according to one embodiment of the present invention. In the charts, Sout(j−1), Sout(j) and Sout(j+1) represent an output voltage (signal) from the (j−1)-th, j-th and (j+1)-th stages Sⱼ₋₁, Sⱼ and Sⱼ₊₁, respectively. Bi and XBi are respectively the first and second control signals for controlling the shift direction of a pulse signal. In this exemplary embodiment shown in FIG. 3, each of Bi and XBi comprises a DC signal characterized with a constant voltage. If Bi is a high voltage signal, e.g., a supply high voltage Vdd, and XBi is a low voltage signal, e.g., a supply low voltage Vss, the pulse will be shifted from the (j−1)-th stage Sⱼ₋₁ to the j-th stage Sⱼ in a forward direction. Otherwise, if Bi is the supply low voltage signal Vss, and XBi is the supply high voltage signal Vdd, the pulse will be shifted from the (j+1)-th stage Sⱼ₊₁ to the j-th stage Sⱼ in a backward direction.

In the forward function operation, the high supply voltage Vdd is applied to the first input IN1 of the j-th stage Sⱼ, and the low supply voltage Vss is applied to the second input IN2 of the j-th stage Sⱼ, respectively. When the output signal Sout(j−1) of the (j−1)-th stage Sⱼ₋₁, which has a high level voltage pulse from t1 to t2, is applied to the third input IN3 of the j-th stage Sⱼ, it turns on the first transistor M. Consequently, the boost point N2 is charged by the high level voltage pulse, which, in turn, turns on the third transistor M3. By applying the clock signal Ck to the fifth input IN5 of the j-th stage Sⱼ the turn-on transistor M3 outputs the output signal Sout(j) of the j-th stage Sⱼ, which has a high level voltage pulse from t2 to t3. Meanwhile, the second transistor M2 plays the discharging role, i.e., receiving the Sout(j+1) of the (j+1)-th stage Sⱼ₊₁, and discharging the boost point N2, which turns off the third transistor M3. In other words, the j-th stage Sⱼ is set (or activated) by the output signal Sout(j−1) of the (j−1)-th stage Sⱼ₋₁, and is reset (or inactivated) by the output signal Sout(j+1) of the (j+1)-th stage Sⱼ₊₁. The output signals Sout(j−1), Sout(j) and Sout(j+1) of the (j−1)-th, j-th and (j+1)-th stages Sⱼ₋₁, Sⱼ and Sⱼ₊₁, are shown in FIG. 3a.

In the backward function operation, the high supply voltage Vdd is applied to the second input IN2 of the j-th stage Sⱼ, and the low supply voltage Vss is applied to the first input IN1 of the j-th stage Sⱼ, respectively. When the output signal Sout(j+1) of the (j+1)-th stage Sⱼ₊₁, which has a high level voltage pulse from t1 to t2, is applied to the fourth input IN4 of the j-th stage Sⱼ, it turns on the second transistor M2. Consequently, the boost point N2 is charged by the high level voltage pulse, which, in turn, turns on the third transistor M3. By applying the clock signal Ck to the fifth input IN5 of the j-th stage Sⱼ the turn-on transistor M3 outputs the output signal Sout(j) of the j-th stage Sⱼ, which has a high level voltage pulse from t2 to t3. Meanwhile, the first transistor M1 plays the discharging role, i.e., receiving the Sout(j−1) of the (j−1)-th stage Sⱼ₋₁, and discharging the boost point N2, which turns off the third transistor M3. In other words, the j-th stage Sⱼ is set (or activated) by the output signal Sout(j+1) of the (j+1)-th stage Sⱼ₊₁, and is reset (or inactivated) by the output signal Sout(j−1) of the (j−1)-th stage Sⱼ₋₁. The output signals Sout(j−1), Sout(j) and Sout(j+1) of the (j−1)-th, j-th and (j+1)-th stages Sⱼ₋₁, Sⱼ and Sⱼ₊₁ are shown in FIG. 3b.

FIG. 4 shows timing charts (waveforms) of input and output signals of the shift register at the (j−1)-th, j-th and (j+1)-th stages Sⱼ₋₁, Sⱼ and Sⱼ₋₁, according to another embodiment of the present invention. In the charts, Sout(j−1), Sout(j) and Sout(j+1) represent an output voltage (signal) from the (j−1)-th, j-th and (j+1)-th stages Sⱼ₋₁, Sⱼ and Sⱼ₊₁, respectively. Bi and XBi are respectively the first and second control signals for controlling the shift direction of a pulse signal. In this embodiment, each of the first bi-directional control signal Bi and the second bi-directional control signal XBi comprises an AC signal characterized with a frequency and a phase. The frequency of the first bi-directional control signal Bi and the frequency of the second bi-directional control signal XBi are substantially identical and the phase of the first bi-directional control signal Bi and the phase of the second bi-directional control signal XBi are substantially reversed. Bi is applied to the first input IN1 of the j-th stage Sⱼ, and XBi is applied to the second input IN2 of the j-th stage Sⱼ, respectively.

In one embodiment, Bi is configured to have a waveform same as or reverse to that of a clock signal Ck (XCk) received in the input IN5 of the stage. If the waveform of Bi is reverse to that of a clock signal Ck (XCk) received in the input IN5 of the stage, and the waveform of XBi is same as that of the clock signal Ck (XCk) received in the input IN5 of the stage, a pulse signal will be shifted from the (j−1)-th stage Sⱼ₋₁ to the j-th stage Sⱼ in a forward direction, as shown in FIG. 4a. Otherwise, if the waveform of Bi is same as that of a clock signal Ck (XCk) received in the input IN5 of the stage, and the waveform of XBi is reverse to that of the clock signal Ck (XCk) received in the input IN5 of the stage, a pulse signal will be shifted from the (j+1)-th stage Sⱼ₊₁ to the j-th stage Sⱼ in a backward direction, as shown in FIG. 4b.

In the forward function operation, when the output signal Sout(j−1) of the (j−1)-th stage Sⱼ₋₁, which has a high level voltage pulse from t1 to t2, is applied to the third input IN3 of the j-th stage Sⱼ, it turns on the first transistor M1. Consequently, the boost point N2 is charged by the high level voltage pulse, which, in turn, turns on the third transistor M3. By applying the clock signal Ck to the fifth input IN5 of the j-th stage Sⱼ the turn-on transistor M3 outputs the output signal Sout(j) of the j-th stage Sⱼ, which has a high level voltage pulse from t2 to t3. Meanwhile, the second transistor M2 plays the discharging role, i.e., receiving the Sout(j+1) of the (j+1)-th stage Sⱼ₊₁, and discharging the boost point N2, which turns off the third transistor M3. In other words, the j-th stage Sⱼ is set (or activated) by the output signal Sout(j−1) of the (j−1)-th stage Sⱼ₋₁, and is reset (or inactivated) by the output signal Sout(j+1) of the (j+1)-th stage Sⱼ₊₁. The output signals Sout(j−1), Sout(j) and Sout(j+1) of the (j−1)-th, j-th and (j+1)-th stages Sⱼ₋₁, Sⱼ and Sⱼ₊₁ are shown in FIG. 4a.

In the backward function operation, when the output signal Sout(j+1) of the (j+1)-th stage Sⱼ₊₁, which has a high level voltage pulse from t1 to t2, is applied to the fourth input IN4 of the j-th stage Sⱼ, it turns on the second transistor M2. Consequently, the boost point N2 is charged by the high level voltage pulse, which, in turn, turns on the third transistor M3. By applying the clock signal Ck to the fifth input IN5 of the j-th stage Sⱼ the turn-on transistor M3 outputs the output signal Sout(j) of the j-th stage Sⱼ, which has a high level voltage pulse from t2 to t3. Meanwhile, the first transistor M1 plays the discharging role, i.e., receiving the Sout(j−1) of the (j−1)-th stage Sⱼ₋₁, and discharging the boost point N2, which turns off the third transistor M3. In other words, the j-th stage Sⱼ is set (or activated) by the output signal Sout(j+1) of the (j+1)-th stage Sⱼ₊₁, and is reset (or inactivated) by the output signal Sout(j−1) of the (j−1)-th stage Sⱼ₋₁. The output signals Sout(j−1), Sout(j) and Sout(j+1) of the (j−1)-th, j-th and (j+1)-th stages Sⱼ₋₁, Sⱼ and Sⱼ₊₁ are shown in FIG. 4b.

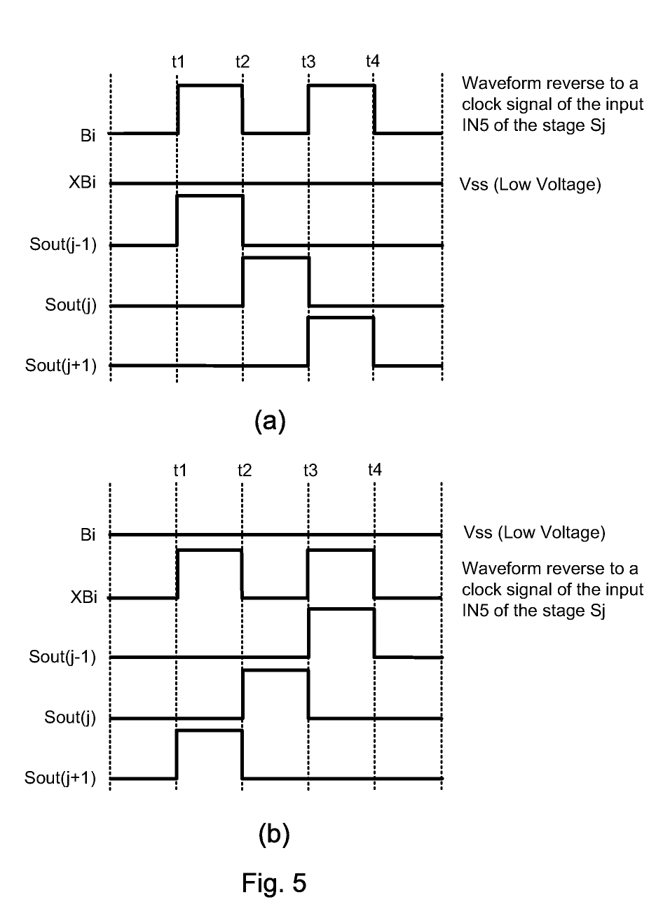

FIG. 5 shows timing charts (waveforms) of input and output signals of the shift register at the (j−1)-th, j-th and (j+1)-th stages Sⱼ₋₁, Sⱼ and Sⱼ₊₁, according to another embodiment of the present invention. In the charts, Sout(j−1), Sout(j) and Sout(j+1) represent an output voltage (signal) from the (j−1)-th, j-th and (j+1)-th stages Sⱼ₋₁, Sⱼ and Sⱼ₊₁, respectively. Bi and XBi are respectively the first and second control signals for controlling the shift direction of a pulse signal. Bi is applied to the first input IN1 of the j-th stage Sⱼ, and XBi is applied to the second input IN2 of the j-th stage Sⱼ, respectively. In this embodiment, for a forward operation direction as shown in FIG. 5a, Bi is an AC signal having a waveform reverse to a clock signal Ck (XCk) received in the input IN5 of the stage, while XBi is a DC signal, which is same as the low voltage Vss. For a backward operation direction as shown in FIG. 5b, Bi is the DC signal, while XBi is the AC signal.

In the forward function operation, when the output signal Sout(j−1) of the (j−1)-th stage Sⱼ₋₁, which has a high level voltage pulse from t1 to t2, is applied to the third input IN3 of the j-th stage Sⱼ, it turns on the first transistor M1. Consequently, the boost point N2 is charged by the high level voltage pulse, which, in turn, turns on the third transistor M3. By applying the clock signal Ck to the fifth input IN5 of the j-th stage Sⱼ the turn-on transistor M3 outputs the output signal Sout(j) of the j-th stage Sⱼ, which has a high level voltage pulse from t2 to t3. Meanwhile, the second transistor M2 plays the discharging role, i.e., receiving the Sout(j+1) of the (j+1)-th stage Sⱼ₊₁, and discharging the boost point N2, which turns off the third transistor M3. In other words, the j-th stage Sⱼ is set (or activated) by the output signal Sout(j−1) of the (j−1)-th stage Sⱼ l, and is reset (or inactivated) by the output signal Sout(j+1) of the (j+1)-th stage Sⱼ₋₁. The output signals Sout(j−1), Sout(j) and Sout(j+1) of the (j−1)-th, j-th and (j+1)-th stages Sⱼ₋₁, Sⱼ and Sⱼ₊₁ are shown in FIG. 5a.

In the backward function operation, when the output signal Sout(j+1) of the (j+1)-th stage Sⱼ₊₁, which has a high level voltage pulse from t1 to t2, is applied to the fourth input IN4 of the j-th stage Sⱼ, it turns on the second transistor M2. Consequently, the boost point N2 is charged by the high level voltage pulse, which, in turn, turns on the third transistor M3. By applying the clock signal Ck to the fifth input IN5 of the j-th stage Sⱼ the turn-on transistor M3 outputs the output signal Sout(j) of the j-th stage Sⱼ, which has a high level voltage pulse from t2 to t3. Meanwhile, the first transistor M1 plays the discharging role, i.e., receiving the Sout(j−1) of the (j−1)-th stage Sⱼ₋₁, and discharging the boost point N2, which turns off the third transistor M3. In other words, the j-th stage Sⱼ is set (or activated) by the output signal Sout(j+1) of the (j+1)-th stage Sⱼ₊₁, and is reset (or inactivated) by the output signal Sout(j−1) of the (j−1)-th stage Sⱼ₋₁. The output signals Sout(j−1), Sout(j) and Sout(j+1) of the (j−1)-th, j-th and (j+1)-th stages Sⱼ₋₁, Sⱼ and Sⱼ₊₁ are shown in FIG. 5b.

The present invention, among other things, discloses a shift register having a plurality of stages electrically coupled to each other in series. Each stage includes a first and second TFT transistor, where the first TFT transistor has a get electrically coupled to the output of the immediately prior stage, a source electrically coupled to the boost point of the stage, and a drain electrically coupled to receive a first control signal, the second TFT transistor has a get electrically coupled to the output of the immediately next stage, a drain electrically coupled to the boost point of the stage, and a source electrically coupled to receive a second control signal that has a polarity oppose to that of the first control signal. For such a configuration, the stage can operate in a forward mode or a backward mode by changing the polarity of the first and second control signals. Accordingly, the invented shift register needs no additional 2-to-2 bi-directional control circuit, thereby reducing power consumption and manufacture costs. Additionally, no additional 2-to-2 bi-directional control circuit in the invented shift register causes no voltage drop in the input signals, which makes the signal trigger levels of the shift register higher, therefore operation responses of the shift register faster, and the shift register more reliable.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A shift register, comprising:
a. a first control line for providing a first bi-directional control signal, Bi;
b. a second control line for providing a second bi-directional control signal, XBi;
c. a first clock signal line for providing a first clock signal, Ck;
d. a second clock signal line for providing a second clock signal, XCk;
e. a reference line for providing a supply voltage, Vss; and
f. a plurality of stages, {Sⱼ}, j=1, 2, . . . , N, N being a positive integer, wherein each stage Sⱼ comprises:
(i). a first input, IN1;
(ii). a second input, IN2;
(iii). a third input, IN3;
(iv). a fourth input, IN4;
(v). a fifth input, IN5, electrically coupled to one of the first clock signal line and the second clock signal line when j is an odd number, or the other of the first clock signal line and the second clock signal line when j is an even number;
(vi). a sixth input, IN6, electrically coupled to the reference line;
(vii). an output, OUT, for outputting an output signal, Sout(j);
(viii). a first transistor M1 having a gate electrically coupled to the third input IN3, a drain electrically coupled to the first input IN1, and a source electrically coupled to a node N1, respectively;
(ix). a second transistor M2 having a gate electrically coupled to the fourth input IN4, a drain electrically coupled to the node N1, and a source electrically coupled to the second input IN2, respectively;
(x). a third transistor M3 having a gate electrically coupled to a node N2 that is electrically coupled to the node N1, a drain electrically coupled to the fifth input IN5, and a source electrically coupled to the output OUT, respectively; and
(xi). a fourth transistor M4 having a gate electrically coupled to a node N3, a drain electrically coupled to the output OUT, and a source electrically coupled to the sixth input IN6, respectively,
wherein the plurality of stages {Sⱼ} is electrically coupled in serial such that the third input IN3 of the i-th stage Sᵢ, i=2, 3, 4, . . . N, is electrically coupled to the output OUT of the (i−1)-th stage Sᵢ₋₁, for receiving a corresponding output signal Sout(i−1) therefrom, and the fourth input IN4 of the k-th stage Sₖ, k=1, 2, 3, . . . (N−1), is electrically coupled to the output OUT of the (k+1)-th stage Sₖ₊₁, for receiving a corresponding output signal Sout(k+1) therefrom.

2. The shift register of claim 1, further comprising a first start pulse input line electrically coupled to the third input IN3 of the first stage S₁ for providing a first start pulse, Sp1, thereto.

3. The shift register of claim 1, further comprising a second start pulse input line electrically coupled to the third input IN4 of the last stage S_{N} for providing a second start pulse, Sp2, thereto.

4. The shift register of claim 1, wherein each Sⱼ further comprises a disable circuit adapted for operably disabling an output of the stage Sⱼ.

5. The shift register of claim 1, wherein each of the first bi-directional control signal Bi and the second bi-directional control signal XBi comprises an AC signal characterized with a frequency and a phase, wherein the frequency of the first bi-directional control signal and the frequency of the second bi-directional control signal are substantially identical and the phase of the first bi-directional control signal and the phase of the second bi-directional control signal are substantially reversed.

6. The shift register of claim 5, wherein the first input IN1 and the second input IN2 of the stage Sⱼ are electrically coupled to the first control line and the second control line, respectively, when j is an odd number, and wherein the first input IN1 and the second input IN2 of the stage Sⱼ are electrically coupled to the second control line and the first control line, respectively, when j is an even number.

7. The shift register of claim 1, wherein each of the first bi-directional control signal Bi and the second bi-directional control signal XBi comprises a DC signal characterized with a constant voltage, wherein when the first bi-directional control signal Bi has a high voltage, the second bi-directional control signal XBi has a low voltage, and vice versa.

8. The shift register of claim 7, wherein the first input IN1 and the second input IN2 of the stage Sⱼ are electrically coupled to the first control line and the second control line, respectively.

9. The shift register of claim 1, wherein one of the first bi-directional control signal Bi and the second bidirectional control signal XBi comprises an AC signal, and the other of the first bi-directional control signal Bi and the second bi-directional control signal XBi comprises a DC signal.

10. The shift register of claim 1, wherein each of the first clock signal Ck and the second clock signal XCk is characterized with a frequency and a phase, wherein the frequency of the first clock signal Ck and the frequency of the second clock signal XCk is substantially identical and the phase of the first clock signal Ck and the phase of the second clock signal XCk is substantially reversed.

11. A shift register, comprising a plurality of stages, {Sⱼ}, j=1, 2, . . . , N, N being a positive integer, wherein each stage Sⱼ comprises:
(a) a first input, IN1, a second input, IN2, a third input, IN3, a fourth input, IN4, a fifth input, IN5 and a sixth input, IN6;
(b) an output, OUT;
(c) a first transistor M1 having a gate electrically coupled to the third input IN3, a drain electrically coupled to the first input IN1, and a source electrically coupled to a node N1, respectively;
(d) a second transistor M2 having a gate electrically coupled to the fourth input IN4, a drain electrically coupled to the node N1, and a source electrically coupled to the second input IN2, respectively;
(e) a third transistor M3 having a gate electrically coupled to a node N2 that is electrically coupled to the node N1, a drain electrically coupled to the fifth input IN5, and a source electrically coupled to the output OUT, respectively; and
(f) a fourth transistor M4 having a gate electrically coupled to a node N3, a drain electrically coupled to the output OUT, and a source electrically coupled to the sixth input IN6, respectively.

12. The shift register of claim 11, wherein the plurality of stages {Sⱼ} is electrically coupled in serial such that the third input IN3 of the i-th stage Sᵢ, i=2, 3, 4, . . . N, is electrically coupled to the output OUT of the (i−1)-th stage S₁₋₁, for receiving a corresponding output signal Sout(i−1) therefrom, and the fourth input IN4 of the k-th stage Sₖ, k=1, 2, 3, . . . (N−1), is electrically coupled to the output OUT of the (k+1)-th stage Sₖ₊₁, for receiving a corresponding output signal Sout(k+1) therefrom.

13. The shift register of claim 12, further comprising a first start pulse input line electrically coupled to the third input IN3 of the first stage S₁ for providing a first start pulse, Sp1, thereto.

14. The shift register of claim 12, further comprising a second start pulse input line electrically coupled to the third input IN4 of the last stage S_{N} for providing a second start pulse, Sp2, thereto.

15. The shift register of claim 12, further comprising:
(a) a first control line for providing a first bi-directional control signal Bi; and
(b) a second control line for providing a second bi-directional control signal XBi.

16. The shift register of claim 15, wherein each of the first bi-directional control signal Bi and the second bi-directional control signal XBi comprises an AC signal characterized with a frequency and a phase, wherein the frequency of the first bi-directional control signal and the frequency of the second bi-directional control signal are substantially identical and the phase of the first bi-directional control signal and the phase of the second bi-directional control signal are substantially reversed.

17. The shift register of claim 16, wherein the first input IN1 and the second input IN2 of the stage Sⱼ are electrically coupled to the first control line and the second control line, respectively, when j is an odd number, and wherein the first input IN1 and the second input IN2 of the stage Sⱼ are electrically coupled to the second control line and the first control line, respectively, when j is an even number.

18. The shift register of claim 15, wherein each of the first bi-directional control signal Bi and the second bi-directional control signal XBi comprises a DC signal characterized with a constant voltage, wherein when the first bi-directional control signal Bi has a high voltage, the second bi-directional control signal XBi has a low voltage, and vice versa.

19. The shift register of claim 18, wherein the first input IN1 and the second input IN2 of the stage Sⱼ are electrically coupled to the first control line and the second control line, respectively.

20. The shift register of claim 15, wherein one of the first bi-directional control signal Bi and the second bi-directional control signal XBi comprises an AC signal, and the other of the first bi-directional control signal Bi and the second bi-directional control signal XBi comprises a DC signal.

21. The shift register of claim 15, further comprising a first clock signal line for providing a first clock signal, Ck, and a second clock signal line for providing a second clock signal, XCk, and wherein the fifth input IN5 of the stage Sⱼ is electrically coupled to one of the first clock signal line and the second clock signal line when j is an odd number, or the other of the first clock signal line and the second clock signal line when j is an even number.

22. The shift register of claim 21, wherein each of the first clock signal Ck and the second clock signal XCk is characterized with a frequency and a phase, wherein the frequency of the first clock signal Ck and the frequency of the second clock signal XCk is substantially identical and the phase of the first clock signal Ck and the phase of the second clock signal XCk is substantially reversed.

23. The shift register of claim 12, further comprising a reference line electrically coupled to the sixth input IN6 of each stage Sⱼ for providing the supply voltage Vss thereto.

24. The shift register of claim 12, wherein each Sⱼ further comprises a disable circuit adapted for operably disabling an output of the stage Sⱼ.

25. The shift register of claim 11, wherein each of the first transistor M1, the second transistor M2, the third transistor M3, and the fourth transistor M4 comprises a field-effect thin film transistor.

26. A shift register, comprising a plurality of stages, {Sⱼ}, j=1, 2, . . . , N, N being a positive integer, wherein the j-th stage Sⱼ comprises:
(a) a first input, IN1, for receiving one of a first bi-directional control signal, Bi, and a second bi-directional control signal, XBi;
(b) a second input, IN2, for receiving the other of the first bi-directional control signal Bi and the second bi-directional control signal XBi;
(c) a third input, IN3;
(d) a fourth input, IN4;
(e) a fifth input, IN5, for receiving a clock signal;
(f) a sixth input, IN6, for receiving a supply voltage, Vss; and
(g) an output, OUT, for outputting an output signal, Sout(j), wherein the plurality of stages {Sⱼ} is electrically coupled in serial such that the third input IN3 of the i-th stage Sᵢ, i=2, 3, 4, . . . N, is electrically coupled to the output OUT of the (i−1)-th stage Sᵢ₋₁, for receiving a corresponding output signal Sout(i−1) therefrom, and the fourth input IN4 of the k-th stage Sₖ, k=1, 2, 3, . . . (N−1), is electrically coupled to the output OUT of the (k+1)-th stage Sₖ₊₁, for receiving a corresponding output signal Sout(k+1) therefrom.

27. The shift register of claim 26, further comprising a first start pulse input line electrically coupled to the third input IN3 of the first stage S₁ for providing a first start pulse, Sp1, thereto.

28. The shift register of claim 26, further comprising a second start pulse input line electrically coupled to the third input IN4 of the last stage S_{N} for providing a second start pulse, Sp2, thereto.

29. The shift register of claim 26, further comprising:
(a) a first control line for providing the first bi-directional control signal Bi; and
(b) a second control line for providing the second bi-directional control signal XBi.

30. The shift register of claim 29, wherein the first bi-directional control signal Bi and the second bi-directional control signal XBi are configured such that when the first bi-directional control signal Bi has a high voltage, the second bi-directional control signal XBi has a low voltage, and vice versa.

31. The shift register of claim 26, further comprising a first clock signal line for providing a first clock signal, Ck, and a second clock signal line for providing a second clock signal, XCk, and wherein the fifth input IN5 of the stage Sⱼ is electrically coupled to one of the first clock signal line and the second clock signal line when j is an odd number, or the other of the first clock signal line and the second clock signal line when j is an even number.

32. The shift register of claim 26, further comprising a reference line electrically coupled to the sixth input IN6 of each stage Sⱼ for providing the supply voltage Vss.

33. The shift register of claim 26, wherein the j-th stage Sⱼ further comprises:
(a) a first transistor M1 having a gate electrically coupled to the third input IN3, a drain electrically coupled to the first input IN1, and a source electrically coupled to a node N1, respectively;
(b) a second transistor M2 having a gate electrically coupled to the fourth input IN4, a drain electrically coupled to the node N 1, and a source electrically coupled to the second input IN2, respectively;
(c) a third transistor M3 having a gate electrically coupled to a node N2 that is electrically coupled to the node N1, a drain electrically coupled to the fifth input IN5, and a source electrically coupled to the output OUT, respectively; and
(d) a fourth transistor M4 having a gate electrically coupled to a node N3, a drain electrically coupled to the output OUT, and a source electrically coupled to the sixth input IN6, respectively.

34. The shift register of claim 33, wherein each of the first transistor M1, the second transistor M2, the third transistor M3, and the fourth transistor M4 comprises a field-effect thin film transistor.
